(19) United States
(12) Patent Application Publication
(10) Pub. No.: US 2023/0050652 A1
(43) Pub. Date: Feb. 16, 2023

(54) ELASTIC BONDING LAYERS FOR SEMICONDUCTOR DIE ASSEMBLIES AND ASSOCIATED SYSTEMS AND METHODS

(71) Applicant: Micron Technology, Inc., Boise, ID (US)

(72) Inventors: Byung Hoon Moon, Taichung (TW); Kyle K. Kirby, Eagle, ID (US)

(21) Appl. No.: 17/673,309

(22) Filed: Feb. 16, 2022

Related U.S. Application Data
(60) Provisional application No. 63/233,438, filed on Aug. 16, 2021.

(51) Int. Cl. H01L 23/00

(52) U.S. Cl. CPC H01L 24/08; H01L 24/80; H01L 24/03; H01L 2224/08145; H01L 2224/80896; H01L 2224/80895; H01L 2224/03013

(57) ABSTRACT

Elastic bonding layers for semiconductor die assemblies, and associated systems and methods are disclosed. In an embodiment, a first semiconductor die includes an elastic bonding layer at a surface, to which a second semiconductor die can be directly bonded to form a bonding interface between the first and second semiconductor dies. At the bonding interface, a first conductive pad of the first semiconductor die can be conjoined to a second conductive pad of the second semiconductor die to form an interconnect during the direct bonding process. In some cases, there may be irregularities at the bonding interface, which may interfere with the bonding process. The elastic bonding layer may include a polymer (or organic) material configured to accommodate stress generated by the irregularities. In some embodiments, a thickness of the elastic bonding layer is predetermined based on a width of the first (or second) conductive pad.

### CROSS-REFERENCE TO RELATED APPLICATION(S)

The present application claims priority to U.S. Provisional Patent Application No. 63/233,438, filed Aug. 16, 2021, the disclosure of which is incorporated herein by reference in its entirety.

### TECHNICAL FIELD

The present disclosure generally relates to semiconductor device assemblies, and more particularly relates to elastic bonding layers for semiconductor die assemblies and associated systems and methods.

### BACKGROUND

Semiconductor packages typically include one or more semiconductor dies (e.g., memory chips, microprocessor chip, imager chip) mounted on a package substrate and encased in a protective covering. The semiconductor die may include functional features, such as memory cells, processor circuits, or imager devices, as well as bond pads electrically connected to the functional features. The bond pads can be electrically connected to corresponding conductive structures of the package substrate, which may be coupled to terminals outside the protective covering such that the semiconductor die can be connected to higher level circuitry.

In some semiconductor packages, two or more semiconductor dies are stacked on top of each other to reduce the footprint of the semiconductor packages. The semiconductor dies in the stack may be arranged in a pattern resembling stair-steps (which may be referred to as “shingle stacking”) such that a portion of the semiconductor dies may be freely accessible—e.g., to attach bond wires to one or more bond pads located in the portion. In some cases, the semiconductor dies may be stacked in a “zig-zag” pattern to increase a space above the bond pads with respect to a semiconductor die overlying above the bond pads so as to facilitate forming the bond wires. Such arrangements, however, tend to increase overall heights of the semiconductor packages. Further, the bond wires may add to the heights and/or introduce delays in signal propagation.

### BRIEF DESCRIPTION OF THE DRAWINGS

Many aspects of the present technology can be better understood with reference to the following drawings. The components in the drawings are not necessarily to scale. Instead, emphasis is placed on illustrating clearly the overall features and the principles of the present technology.

FIGS. 1A-1D (referred to collectively as “FIG. 1”) illustrate various stages of process steps for direct bonding schemes.

FIG. 2 is an example schematic diagram of a semiconductor die assembly.

FIGS. 3A and 3B (referred to collectively as “FIG. 3”) illustrate schematic views of a semiconductor die including a dielectric structure in accordance with embodiments of the present technology.

FIG. 4 is a schematic diagram of a semiconductor die assembly in accordance with embodiments of the present technology.

FIG. 5 is a block diagram schematically illustrating a system including a semiconductor die assembly in accordance with embodiments of the present technology.

FIG. 6 is a flowchart of a method of making a semiconductor die having a dielectric structure and a conductive pad in accordance with embodiments of the present technology.

### DETAILED DESCRIPTION

Specific details of several embodiments of elastic bonding layers for semiconductor die assemblies, and associated systems and methods are described below. The term “semiconductor device or die” generally refers to a solid-state device that includes one or more semiconductor materials. Examples of semiconductor devices (or dies) include logic devices or dies, memory devices or dies, controllers, or microprocessors (e.g., central processing unit (CPU), graphics processing unit (GPU)), among others. Such semiconductor devices may include integrated circuits or components, data storage elements, processing components, and/or other features manufactured on semiconductor substrates. Further, the term “semiconductor device or die” can refer to a finished device or to an assembly or other structure at various stages of processing before becoming a finished functional device. Depending upon the context in which it is used, the term “substrate” may include a semiconductor wafer, a package substrate, a semiconductor device or die, or the like. Suitable steps of the methods described herein can be performed with processing steps associated with fabricating semiconductor devices (wafer-level and/or die-level) and/or manufacturing semiconductor packages.

Various computing systems or environments, e.g., high-performance computing (HPC) systems, require high bandwidth and low power consumption. Certain schemes of forming interconnects between semiconductor dies (e.g., a direct bonding scheme) may facilitate satisfying the requirements, as well as providing form-factors suitable for scaling physical dimensions (e.g., heights) of semiconductor die assemblies of the HPC systems. The direct bonding scheme includes individual conductive components (e.g., copper pads, conductive pads) of a first semiconductor die (or a first wafer including the first semiconductor die) aligned and directly bonded to corresponding one of conductive components of a second semiconductor die (or a second wafer including the second semiconductor die). Further, a dielectric material surrounding each of the conductive components of the first semiconductor die can be directly bonded to another dielectric material surrounding each of the conductive components of the second semiconductor die. In other words, the bonding interface includes two or more dissimilar materials of the first semiconductor die directly bonded to corresponding materials of the second semiconductor die (e.g., between dielectric materials, between conductive materials) to form interconnects and surrounding dielectric layers. As such, the direct bonding scheme may also be referred to a combination bonding scheme, a hybrid bonding scheme, or the like.

In some embodiments, the conductive materials include copper (or other suitable conductive materials or metals, such as tungsten) as a primary constituent, and the dielectric materials include silicon oxides (e.g., SiO₂), silicon nitrides (e.g., Si₃N₄), silicon carbon nitrides (e.g., SiCN), silicon carbonates (e.g., SiCO), or the like. During the direct bonding process, the dielectric materials of the first and second semiconductor dies (or the first and second wafers including the first and second semiconductor dies) are brought together such that the dielectric materials adhere to each other. Subsequently, the semiconductor dies are annealed at an elevated temperature such that the conductive materials of the first and second semiconductor dies are conjoined to form permanent bonding—e.g., metallurgical bonding. Additionally, the dielectric materials may enhance their bonding strength during the annealing process. If any irregularities (e.g., defects, particles, over-growing copper pads) exist at the bonding interface (which may also be referred to as a mating interface or a bond line), such irregularities would weaken the bonding strength between the semiconductor dies (or the wafers), for example by forming voids surrounding the irregularities or by delaminating the dielectric materials, at least due to stiffness and/or brittleness of the dielectric materials.

In some cases, even if the direct bonding forms to hold the two semiconductor dies (or wafers) bonded together, the voids present at the bonding interface may interfere with forming robust interconnects between the conductive components. If portions of conductive components are not conjoined (e.g., fused) due to the voids, the interconnects including partially conjoined conductive components may have higher than desired resistance values. If the conductive components fail to form continuous conductive paths, the interconnects may suffer from electrical opens. In some cases, the voids may include the conductive materials that originate from the conductive components connected to the voids—e.g., through various mechanisms causing the conductive materials to migrate, such as extension, extrusion, diffusion, or the like. If the voids are large enough to reach multiple conductive components, the voids may serve as conduits for the conductive materials (e.g., Cu) to migrate such that undesired leakage paths and/or electrical shorts can occur between the conductive components. Accordingly, the environment for the direct bonding process needs to be ultra clean in order to avoid the particles at the bonding surfaces, which in turn, tends to increase the manufacturing cost.

In some embodiments, the conductive pads may have recessed surfaces with respect to the surface of the dielectric materials such that when the dielectric materials of the semiconductor dies adhere to each other (e.g., prior to the annealing process), bonding of the dielectric materials can be accomplished without any interference from protruded bond pads. Further, the recess amount (e.g., a depth of recess, recess depth) may be devised to be within a certain range such that the conductive materials (e.g., copper) can be suitably conjoined to each other (e.g., during the annealing process) without compromising the bonding strength or the interconnect characteristics. For example, if the depths of recess of the conductive pads are insufficient (e.g., too shallow), the conductive materials, during the annealing process, may expand to pry open (e.g., pull apart, delaminate) the bonding interface, at least in the region proximate to the conductive pads. On the other hand, if the depths of recess are excessive (e.g., too deep), the conductive materials, during the annealing process, may not be sufficiently conjoined to form robust interconnects.

Accordingly, controlling the recess amounts can impose strict conditions to various factors that can affect the recess amounts of the conductive pads. For example, conductive pads may be designed (e.g., laid out) to have widths of certain ranges to restrict variations in the recess depths. In some embodiments, the conductive pads may be partitioned or be surrounded with dummy pads to satisfy certain areal density requirements of the conductive pads. In some cases, elaborate targeting of the recess amounts may be carried out to determine adequate process conditions—e.g., over-polish targeting during chemical-mechanical polish (CMP) process steps used to generate the conductive pads. Even so, statistical random process variations (e.g., life of CMP pads, variations in CMP slurries) may present challenges to the recess amount control.

The present technology mitigates risks associated with forming compromised bonding interfaces (e.g., voids weakening bonding strength, interconnects having partially conjoined conductive components, lateral leakage paths and/or electrical shorts between interconnects, over-grown copper pads resulting in delaminated bonding interface) by providing elastic bonding layers at the bonding interface. Such a layer with elastic properties can tolerate the irregularities (e.g., particles, defects, excessive copper volume expansion tending to delaminate the bonding interface, copper pads protruded beyond the dielectric surface) at the bonding interface—e.g., by conforming to the shapes of the irregularities, by accommodating stress (or strain) generated by the irregularities. Further, the elastic layers may facilitate the hybrid bonding process by improving bonding strength to hold the semiconductor dies together. In some embodiments, the elastic bonding layer may include a polymer (or organic) material that is flexible to deform and/or to absorb stress in response to localized pressure generated by the irregularities during the bonding process.

In this regard, the combination including the elastic bonding layer and one or more dielectric layers (e.g., silicon oxides, silicon nitrides, silicon carbon nitrides, silicon carbonates) may be regarded as a composite dielectric structure. The composite dielectric structure including the elastic bonding layer can relax requirements associated with tightly controlling recess amounts of the conductive pads—e.g., requirements associated with CMP process and/or design rules for the conductive pads. As a result, the bonding interface can be improved to have enhanced bonding strength at least due to increased bonding areas, reduced quantities of interconnects having high resistance, reduced probabilities of forming leakage paths between interconnects, reduced probability of delaminating the bonding interface or otherwise degrading the bonding interface at least partially due to excessive copper volume expansion, among others. Additionally, or alternatively, the direct bonding process employing the composite dielectric structures may be carried out in an environment with relatively lenient requirements directed to the particles, which in turn, may reduce the manufacturing cost.

As used herein, the terms “front,” “back,” “vertical,” “lateral,” “down,” “up,” “upper,” and “lower” can refer to relative directions or positions of features in the semiconductor device assemblies in view of the orientation shown in the Figures. For example, “upper” or “uppermost” can refer to a feature positioned closer to the top of a page than another feature. These terms, however, should be construed broadly to include semiconductor devices having other orientations. Unless stated otherwise, terms such as “first” and “second” are used to arbitrarily distinguish between the elements such terms describe. Thus, these terms are not necessarily intended to indicate temporal or other prioritization of such elements.

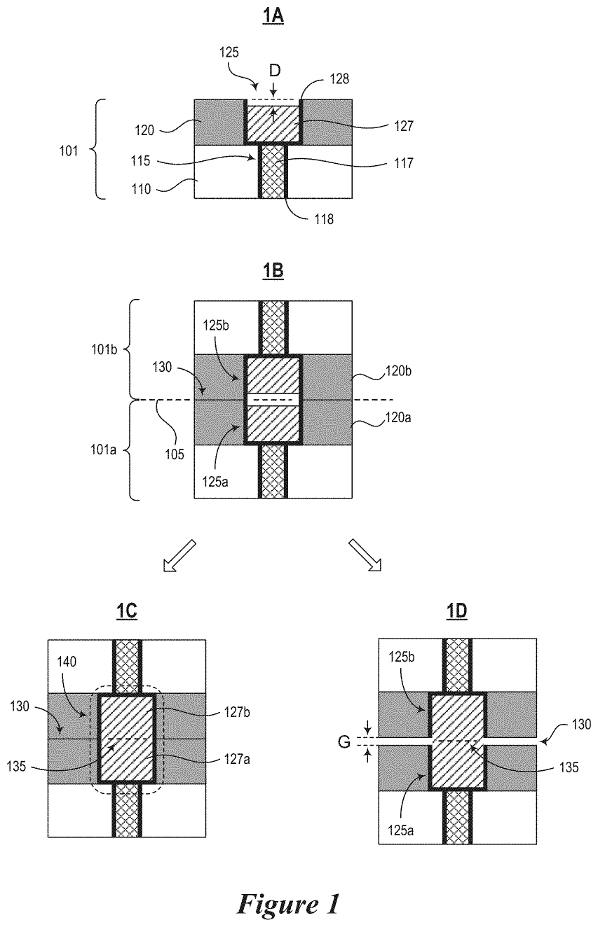

FIG. 1 illustrates various stages of process steps for direct bonding schemes. FIG. 1A illustrates a portion of a semiconductor die 101 with a substrate 110 having integrated circuitry (not shown) and a through-substrate via (TSV) 115 coupled with the integrated circuitry. In some embodiments, the TSV 115 includes a first conductive material 117 (e.g., tungsten) and a conductive barrier layer 118 (e.g., TiN). The semiconductor die 101 also includes a conductive pad 125 formed in a dielectric layer 120 (e.g., silicon oxides, silicon nitrides, silicon carbon nitrides, silicon carbonates, or a combination thereof), which is electrically connected to the TSV 115. In some embodiments, the conductive pad 125 includes a second conductive material 127 (e.g., copper) and another conductive barrier layer 128 (e.g., TaN).

The conductive pad 125 depicted in FIG. 1A includes a surface recessed by a depth D with respect to the surface of the dielectric layer 120. In some embodiments, CMP process steps are used to form the conductive pad 125, and the recess may be a result of the CMP process. For example, the recess may be formed during over-polishing steps that remove excessive conductive material 127 on the surface of the dielectric layer 120. Additionally, or alternatively, the amount of recess (e.g., the recess depth D) may be targeted to ensure the surface of the conductive pad 125 not to protrude above the surface of the dielectric layer 120—e.g., to avoid such protruded conductive pads 125 interfering with the bonding process described with reference to FIG. 1B. Further, the amount of recess may be targeted to be within a certain range such that the conductive materials 127 can form an interconnect 140 as described with reference to FIG. 1C without compromising the bonding integrity.

FIG. 1B illustrates two semiconductor dies 101a and 101b (or two wafers including the semiconductor dies 101a/b) are attached together such that dielectric materials of the top semiconductor die 101b and bottom semiconductor die 101a adhere to each other to form dielectric-to-dielectric bonding 130 at the bonding interface 105. In some embodiments, the dielectric surfaces are activated (e.g., using a plasma treatment process) to facilitate bonding of the dielectric surfaces. Also, conductive pads (e.g., the top conductive pad 125b and the bottom conductive pad 125a) of the top and bottom semiconductor dies are aligned to face each other but are not connected to each other due to the recessed surfaces of the conductive pads 125a/b.

FIG. 1C illustrates that the bonded dies/wafers are annealed in an elevated temperature (e.g., around 200° C.) such that the conductive materials of the top and bottom conductive pads 125a/b may expand toward each other in response to receiving thermal energy (e.g., due to the mismatch in coefficients of thermal expansion (CTE) between the conductive materials and the dielectric materials) within an open space defined by the recess and the dielectric material surrounding the bond pads. When the surfaces of the top and bottom conductive materials are in contact, the conductive materials are conjoined (e.g., via atomic migration (intermixing, diffusion) from one conductive material to another conductive material) to form metal-to-metal bonding 135—e.g., metallurgical bonding, permanent bonding. Once the metallurgical bonding is formed between the conductive pads 125a/b (thus, forming the interconnect 140), the conductive materials do not separate (or sever) when the bonded dies/wafers are brought to the ambient temperature or operating temperatures of the semiconductor die assemblies.

FIG. 1D illustrates that the dielectric-to-dielectric bonding 130 can be separated (e.g., delaminated or pulled apart as denoted by a gap G) during the anneal process if the recess amount is insufficient such that the conductive materials of the top and bottom conductive pads 125a/b expand to conjoin and continue to expand to pry open the dielectric-to-dielectric bonding 130—e.g., forming over-grown conductive pads. As such, although the metal-to-metal bonding 135 has been formed, overall bonding integrity may be deteriorated, due to the dielectric-to-dielectric bonding 130 compromised at least at the vicinity of the conductive pads 125a/b. If the separation (delamination) becomes prevalent across the bonding interface 105, the semiconductor dies 101a and 101b may be completely detached.

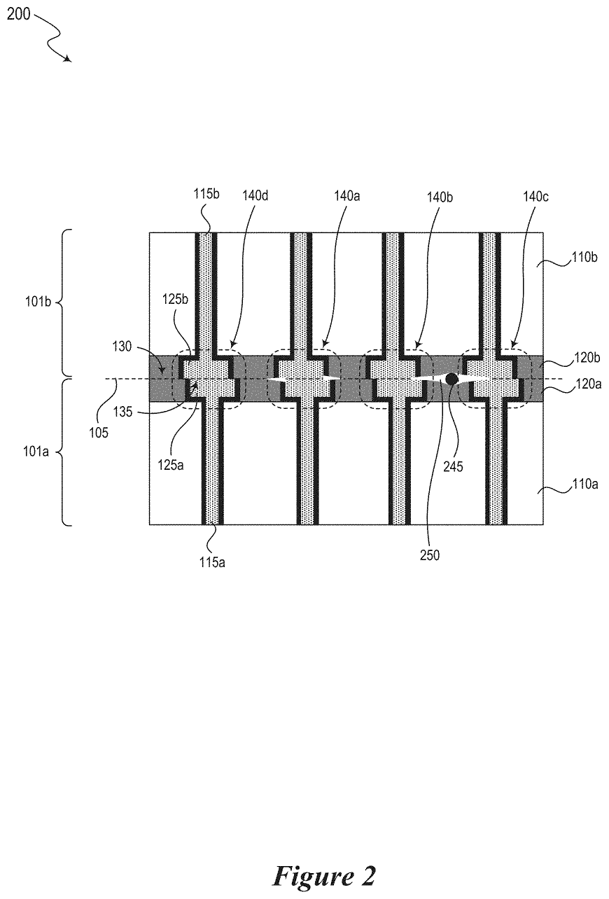

FIG. 2 is an example schematic diagram 200 of a semiconductor die assembly. The diagram 200 illustrates various irregularities that may be present at the bonding interface 105 between semiconductor dies 101 (also identified individually as 101a/b) described with reference to FIG. 1. Certain details of the semiconductor dies 101 are omitted in the diagram 200 (e.g., distinctions between conductive materials for the TSVs 115 and the conductive pads 125, portions of the conductive barrier layer 128 in contact with the TSVs 115) for clear illustration of overall features and the principles of the present technology.

At the bonding interface 105, the dielectric layers 120a/b are directly bonded (e.g., conjoined, fused) to form the dielectric-to-dielectric bonding 130. Also, the conductive components 125a/b are directly bonded (e.g., conjoined, fused) to form the metal-to-metal bonding 135 at the bonding interface 105. Accordingly, the bonding interface 105 includes both the dielectric-to-dielectric bonding 130 and the metal-to-metal bonding 135, and may be referred to as combinational bonding interface or a hybrid bonding interface. The diagram 200 illustrates interconnects 140 (also identified individually as 140a-d) that each includes the conjoined conductive components 125.

The bonding interface 105 may include irregularities, such as defects, particles, over-grown conductive pads, or conductive pads protruded beyond the dielectric surface, resulting in at least locally incomplete dielectric-to-dielectric bonding. For example, the diagram 200 illustrates an irregularity 245 (e.g., a particle, a defect) at the bonding interface 105. The dielectric layers 120 tend to be stiff and/or brittle such that the dielectric layers 120 may not locally conform to the irregularity 245 during the direct bonding process. As a result, voids (e.g., the void 250 depicted in the diagram 200) may form around the irregularities at the bonding interface 105. As such, although overall direct bonding between the dielectric layers 120 may be established to bond the semiconductor dies 101 together, the bonding interface 105 may include such voids associated with the irregularities. Presence of the voids reduces overall area of the dielectric-to-dielectric bonding 130, and thus decreases the bonding strength of the bonding interface 105.

In some cases, certain voids formed at the bonding interface 105 may be sufficiently large (or located proximate to conductive components 125) to interfere with (hinder, impede) forming the metal-to-metal bonding 135. For example, the void 150 may expand (encroach) into the interconnect 140c such that the metal-to-metal bonding of the interconnect 140c is compromised. As a result, the interconnect 140c may have a higher resistance than other interconnects 140 (e.g., the interconnect 140d free from any irregularities). Such variations in electrical characteristics of the interconnects 140 may degrade performance of the semiconductor die assembly. If the size of the void 250 is large enough to prevent the interconnects 140 to form continuous current paths (e.g., resulting in electrical opens), such interconnects 140 may cause the semiconductor die assembly to fail to operate.

In some embodiments, the metal-to-metal bonding 135 may be formed by thermally expanding (e.g., through volume expansion in response to thermal energy applied during the anneal process) the conductive materials of the conductive components 125 (e.g., copper) after the semiconductor dies 101 are brought in contact with each other as described in with reference to FIG. 1. Accordingly, the voids, if connected to the conductive components 125, may serve as conduits, through which the conductive materials can migrate. If the void 250 is large enough to bridge (or otherwise connect) two or more interconnects 140 as illustrated in the diagram 200, the void 250 including traces of conductive materials may result in undesired leakage paths and/or electrical shorts between the interconnects—e.g., between the interconnect 140b and the interconnect 140c.

The interconnect 140a illustrates that the dielectric-to-dielectric bonding 130 can be separated or delaminated (e.g., pulled apart, at least in a region proximate to the interconnect 140a as described with reference to FIG. 1D) during the anneal process if the recess amounts of the conductive components 125 are insufficient such that the conductive materials of the top and bottom conductive pads expand to conjoin and continue to expand to pry open (delaminate) the dielectric-to-dielectric bonding 130. As such, although the interconnect 140a has been formed, overall bonding integrity may be deteriorated, due to the dielectric-to-dielectric bonding 130 compromised (e.g., pulled apart, delaminated) at least at the vicinity of the interconnect 140a. In some cases, the delamination may not be limited to the vicinity of the interconnect 140a, and may propagate to eventually fail the direct bonding.

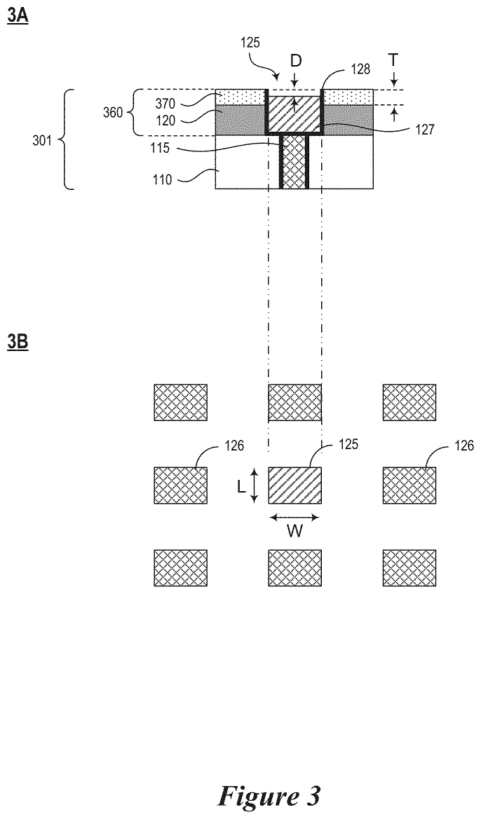

FIG. 3 illustrates schematic views of a semiconductor die 301 including a dielectric structure 360 in accordance with embodiments of the present technology. The semiconductor die 301 may be an example of or include aspects of the semiconductor die 101 described with reference to FIG. 1. For example, the cross-sectional view of FIG. 3A depicts the semiconductor die 301 including the substrate 110 having integrated circuitry (not shown) and the TSV 115 coupled with the integrated circuitry. The semiconductor die 301 also includes the conductive pad 125, which is electrically connected to the TSV 115. The dielectric structure 360 includes an elastic bonding layer 370 over the dielectric layer 120. As such, the dielectric structure 360 may be referred to as a composite dielectric structure 360.

The conductive pad 125 extends through the elastic bonding layer 370 and operatively coupled to the integrated circuitry through the TSV 115. The footprint of the conductive pad 125 may correspond to a square (which may appear as a circle after patterning process steps), a rectangle (which may appear as an oval (or a racetrack) shape after patterning process steps), or any suitable polygon shapes. Further, the conductive pad 125 includes a surface recessed by a depth D with respect to the surface of the dielectric structure 360 (i.e., the surface of the elastic bonding layer 370). In some embodiments, the recessed surface of the conductive pad 125 may be a result of CMP process steps. Further, the amount of recess (e.g., the recess depth D, which may also be referred to as dishing of the conductive pad 125) may be a function of lateral dimensions (e.g., widths, lengths, diameters, or the like, perpendicular to the recess depth D) of the conductive pad 125.

For example, the CMP process steps tend to generate relatively greater recess depths for the conductive pads 125 with relatively greater lateral dimensions. Accordingly, the conductive pads 125 may be designed (e.g., laid out) to have surface areas within certain ranges, determined by comparable widths and lengths (e.g., rectangles with similar widths and lengths, including squares). By way of example, the conductive pads 125 may include lateral dimensions that are approximately a few micrometers (μm) ranges. In other examples, the conductive pads 125 may include lateral dimensions that are approximately several tens of nanometer (nm) ranges. In this manner, variations in the recess depth D across multiple conductive pads 125 (e.g., across the semiconductor die 301, across the semiconductor wafer including a plurality of semiconductor dies 301) can be maintained within certain specifications (e.g., 10 nm or less). If the conductive pads 125 are laid out to have comparable widths and lengths, the recess depths D may be proportional to the greater of the two—e.g., widths if it is greater than lengths.

In some embodiments, the conductive pad 125 may be surrounded by dummy conductive pads 126 as depicted in the plan-view of FIG. 3B. In this manner, areal density of the conductive pads can be maintained within certain ranges to reduce variations in the recess depth D across multiple conductive pads 125. The dummy conductive pads 126 may be electrically isolated (e.g., not connected to TSV 115 or any other active circuit elements of the semiconductor die 301). Although the dummy conductive pads 126 are depicted to have the same size (and shape) as the conductive pads 125 in FIG. 3B, in some embodiments, sizes (and shapes) of the dummy conductive pads 126 may be different than the conductive pads 125. Further, the dummy conductive pads 126 can be more (or less) densely populated than as shown in FIG. 3B. In some embodiments, the conductive pads 125 can be partitioned into two or more segments (those which may be electrically connected to each other at a lower level (e.g., underneath the partitioned conductive pads 125) to satisfy certain resistance requirements for the conductive pads 125) to reduce variations in the recess depth D.

The elastic bonding layer 370 of the composite dielectric structure 360 may facilitate tolerating various irregularities during the direct bonding process to improve the quality of the bonding interface—e.g., mitigating adverse effects originating from the irregularities described with reference to FIG. 2. In some embodiments, the elastic bonding layer 370 includes polymer or organic materials that can accommodate the stress (or strain) stemming from the irregularities at the bonding interface (mating interface, bond line). For example, the elastic bonding layer 370 may deform to absorb the stress if there are too much copper (e.g., due to insufficient recess depths) in either or both of the mating conductive pads, resulting in over-growth of the copper during the anneal process—e.g., swelling of the copper beyond the available space provided by the recess. In this manner, the elastic bonding layer 370 can prevent delamination at the dielectric-to-dielectric bonding interface (e.g., the dielectric-to-dielectric bonding 130) and further propagation (or lateral encroachment) of such delamination at the bond line.

Accordingly, the elastic bonding layer 370 may be regarded as a “resistive,” “spring-like,” “stretchy,” “stress-relief,” or “rubbery” layer. In this manner, the composite dielectric structure 360 can provide flexibility to tolerate the irregularities at the bonding interface. In some embodiments, the elastic bonding layer 370 includes at least one of polyimide, polybenzoxazole (PBO), polysiloxane-based material (e.g., polydimethylsiloxane (PDMS)), or a sol-gel material. In some embodiments, the elastic bonding layer 370 has a modulus of elasticity of approximately 2 GPa or less. In some embodiments, the elastic bonding layer 370 may conform to one or more irregularities (e.g., the irregularity 245) present at the bonding interface—e.g., the surface of the elastic bonding layer 370. In other words, the elastic bonding layer 370 can be regarded as flexible (or compliant) enough to deform in response to the localized pressure generated by the defects or to absorb or accommodate the stress (or strain) generated by over-growth of copper (e.g., z-directional displacements perpendicular to the bond line).

In some embodiments, the thickness of the elastic bonding layer 370 (denoted as T in FIG. 3) is predetermined based on the recess depth D of the conductive pad 125. In view of the recess depth D being proportional to the lateral dimensions (e.g., widths) of the conductive pad 125, the thickness of the elastic bonding layer 370 can be determined by the lateral dimensions of the conductive pad 125. In this manner, when the design rules associated with the conductive pad 125 (e.g., widths, lengths, spacing between the conductive pads, dummy conductive pads placements) are determined, the thickness of the elastic bonding layer 370 can be predetermined. In some embodiments, the thickness of the elastic bonding layer 370 is at least ten (10) times the recess depth. It should be understood that suitable thicknesses of the elastic bonding layer 370 may vary based on numerous factors, such as sizes of the conductive pads 125, volume of conductive materials in the conductive pads 125 (hence the thickness of the conductive pad 125 for given lateral dimensions), the recess depth amounts, the thermal energy provided to the semiconductor dies during the annealing process, cleanliness of the process environments (e.g., particle/defect sizes expected for the elastic bonding layer 370 to accommodate), elasticity of the bonding layer 370, among others.

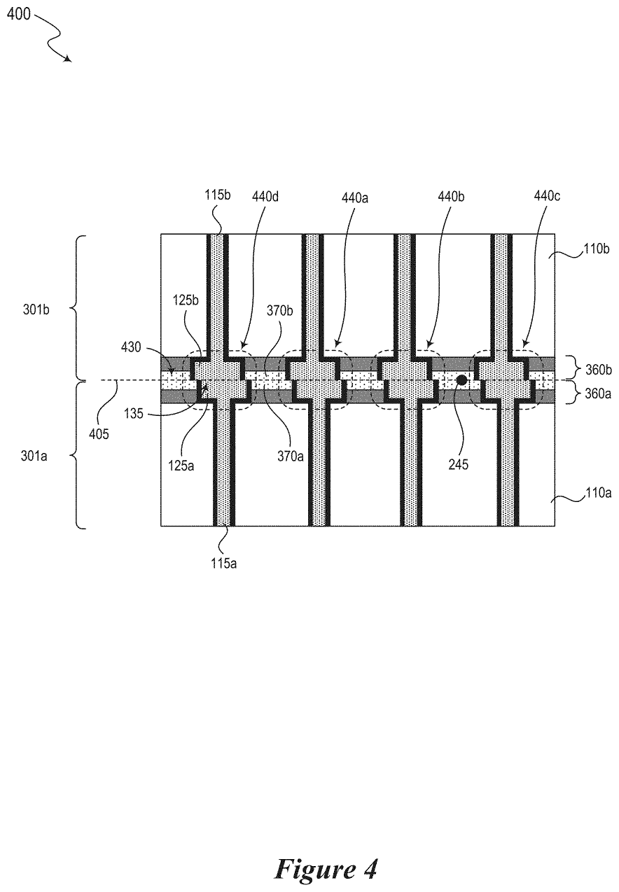

Although the diagram 3A illustrates the conductive pad 125 operatively coupled with the integrated circuitry through the TSV 115—i.e., the conductive pad 125 and the integrated circuitry located at opposite sides of the semiconductor die 301, the present technology is not limited thereto. For example, the conductive pad 125 can be operatively coupled with the integrated circuitry through conductive traces (e.g., suitable metallization schemes built over the integrated circuitry) such that the conductive pad 125 and the integrated circuitry are located at the same side of the semiconductor die 301—e.g., the front side of the semiconductor die 301. As such, although the bonding interface 405 described with reference to FIG. 4 may represent the backsides of the semiconductor dies 301a/b that are directed bonded, the present technology can be utilized for directly bonding the front sides of the semiconductor dies 301a/b, as well as for directly bonding the front side and back side of the semiconductor dies 301a/b.

FIG. 4 is a schematic diagram 400 of a semiconductor die assembly in accordance with embodiments of the present technology. The diagram 400 illustrates a bonding interface 405 between the semiconductor dies 301a/b directly bonded to each other. As described with reference to FIG. 3, the dielectric structure 360a/b include the elastic bonding layers 370a/b. At the bonding interface 405, the semiconductor die assembly includes a bonding interface 430 between the elastic bonding layers 370a/b and the metal-to-metal bonding 135. Further, interconnects 440 (also identified individually as 440a-d) are formed during the direct bonding process (e.g., during the anneal process). Similar to the bonding interface 105 described with reference to FIG. 1, the bonding interface 405 may include irregularities (e.g., defects, particles, over-grown conductive pads, conductive pads protruded beyond the elastic bonding layer surface). For example, the diagram 400 illustrates the irregularity 245 (e.g., a defect, a particle) at the bonding interface 405.

As described with reference to FIG. 3, the elastic bonding layers 370a/b are configured to accommodate one or more irregularities at the bonding interface 405. As such, a void (e.g., the void 250 depicted in FIG. 2) associated with the irregularity 245 may be absent at the bonding interface 405 (or substantially reduced in its size (not shown)). Further, even if the conductive materials (e.g., copper) over grows (e.g., the interconnect 140a described with reference to FIG. 2), the elastic bonding layers 370a/b can accommodate the stress (or strain) such that the bonding interface 430 can maintain its integrity (e.g., preventing the bonding interface from delaminating). In some cases, the elastic bonding layers 370a/b can accommodate one or more conductive pads protruded above the bonding interface 430 when the semiconductor dies 301a/b brought together (e.g., prior to the annealing process).

In this manner, the bonding interface 405 may be improved when compared to the bonding interface 105 described with reference to FIG. 2. For example, the bonding interface 405, in comparison to the bonding interface 105, may have enhanced bonding strength at least due to increased bonding areas, reduced quantities of interconnects 440 having high resistance (or electrical opens), reduced probabilities of forming leakage paths between interconnects 440, among others. Further, the bonding interface 430 between the elastic bonding layers 370a/b may have stronger bonding strength when compared to the dielectric-to-dielectric bonding 130. Additionally, or alternatively, the direct bonding process may be carried out in an environment with relatively lenient requirements directed to the particles (e.g., particle sizes and/or distributions), which in turn, may reduce the manufacturing cost of the semiconductor die assembly.

Although the foregoing example embodiment of FIG. 4 includes both semiconductor dies (e.g., the semiconductor dies 301a/b) having the composite dielectric structure 360a/b, the present technology is not limited thereto. For example, in some embodiments, the semiconductor die 301b may be replaced with the semiconductor die 101—i.e., a semiconductor die not including the composite dielectric structure 360 (i.e., without the elastic bonding layer 370). In such embodiments, the composite dielectric structure 360a of the semiconductor die 301a may be modified (e.g., by increasing the thickness of the elastic bonding layer 370a) such that the adverse effect due to one or more irregularities can be mitigated by the single composite dielectric structure 360a of the semiconductor die 301a.

In some embodiments, a semiconductor die assembly (e.g., the semiconductor die assembly of the diagram 400) includes a substrate die, and a semiconductor die (e.g., a semiconductor die 301a) attached to the substrate die. The semiconductor die may include a semiconductor substrate having integrated circuitry, a dielectric structure over the semiconductor substrate, the dielectric structure (e.g., the dielectric structure 360a) including an elastic bonding layer (e.g., the elastic bonding layer 370a) located at a first side of the dielectric structure facing away from the semiconductor substrate, and a copper pad (e.g., the conductive pad 125a) included in the dielectric structure, where the copper pad extends through the elastic bonding layer and is operatively coupled to the integrated circuitry. Further, a thickness of the elastic bonding layer is predetermined based, at least in part, on a width of the copper pad, the width being generally perpendicular to the thickness.

In some embodiments, the elastic bonding layer includes a polymer material configured to accommodate stress generated by an irregularity at the first side. In some embodiments, the semiconductor die is a first semiconductor die and the copper pad is a first copper pad, and the semiconductor die assembly further includes a second semiconductor die (e.g., the semiconductor die 301b) directly bonded to the first semiconductor die at the first side, where the second semiconductor die includes a second copper pad (e.g., the conductive pad 125b) directly bonded to the first copper pad. In some embodiments, the semiconductor die is a first semiconductor die and the elastic bonding layer is a first elastic bonding layer, and the semiconductor die assembly further includes a second semiconductor die (e.g., the semiconductor die 301b) directly bonded to the first semiconductor die at the first side, wherein the second semiconductor die includes a second elastic bonding layer (e.g., the elastic bonding layer 370b) directly bonded to the first elastic bonding layer.

In some embodiments, the copper pad of the first semiconductor die is a first copper pad, and the semiconductor die assembly further includes a second copper pad (e.g., the conductive pad 125b) of the second semiconductor die directly bonded to the first copper pad at the first side. In some embodiments, the substrate die corresponds to an interposer die or a logic die, and the first and second semiconductor dies correspond to memory dies.

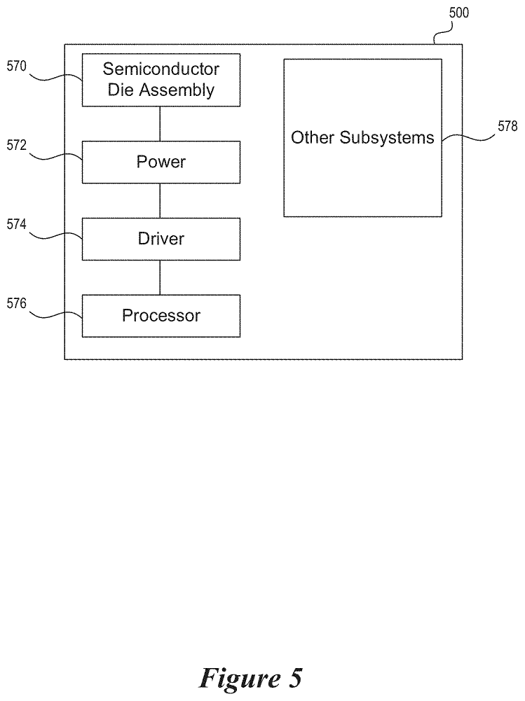

FIG. 5 is a block diagram schematically illustrating a system 500 including a semiconductor die assembly in accordance with embodiments of the present technology. The system 500 can include a semiconductor device assembly 570, a power source 572, a driver 574, a processor 576, and/or other subsystems or components 578. The semiconductor device assembly 570 can be incorporated into any of a myriad of larger and/or more complex systems, a representative example of which is the system 500 shown schematically in FIG. 5. The semiconductor die assembly described with reference to FIG. 4 may be included in the semiconductor device assembly 570 of the system 500.

The semiconductor device assembly 570 can have features generally similar to the semiconductor die assembly described herein with reference to FIG. 4. For example, the semiconductor device assembly 570 may include two semiconductor dies that are directly bonded to each other. At least one of the semiconductor dies may include a dielectric structure having an elastic bonding layer that can tolerate (or accommodate) irregularities (e.g., defects, particles, over-grown copper pads) present at the bonding interface. Further, at the bonding interface, the semiconductor die assembly 570 includes interconnects (e.g., interconnects 440) formed by conjoining conductive pads (e.g., conductive pads 125a/b) during the direct bonding process. The elastic bonding layer may have a thickness predetermined based on a width of the conductive pads. In some embodiments, the elastic bonding layer may include a polymer (or organic) material configured to accommodate stress (or strain) generated by the irregularities at the bonding interface during the direct bonding process steps.

The resulting system 570 can perform any of a wide variety of functions, such as memory storage, data processing, and/or other suitable functions. Accordingly, representative systems 570 can include, without limitation, hand-held devices (e.g., mobile phones, tablets, digital readers, and digital audio players), computers, and appliances. Components of the system 570 may be housed in a single unit or distributed over multiple, interconnected units (e.g., through a communications network). The components of the system 570 can also include remote devices and any of a wide variety of computer readable media.

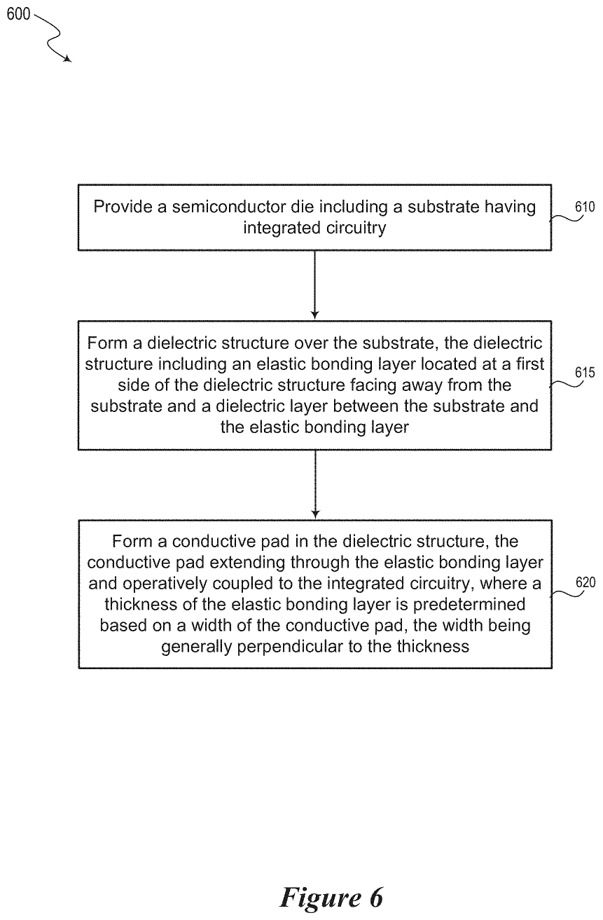

FIG. 6 is a flowchart 600 of a method of making a semiconductor die having a dielectric structure and a conductive pad in accordance with embodiments of the present technology. The flowchart 600 may include aspects of methods as described with reference to FIGS. 1 through 4.

The method comprises providing a semiconductor die including a substrate having integrated circuitry (box 610). The method further comprises forming a dielectric structure over the substrate, the dielectric structure including an elastic bonding layer located at a first side of the dielectric structure facing away from the substrate and a dielectric layer between the substrate and the elastic bonding layer (box 615). The method further comprises forming a conductive pad in the dielectric structure, the conductive pad extending through the elastic bonding layer and operatively coupled to the integrated circuitry, where a thickness of the elastic bonding layer is predetermined based, at least in part, on a width of the conductive pad, the width being generally perpendicular to the thickness (box 620).

In some embodiments, forming the conductive pad in the dielectric structure includes forming a cavity in the dielectric structure, the cavity extending through the elastic bonding layer and at least partially into the dielectric layer, filling the cavity with copper, and removing excessive copper on the first side. In other embodiments, forming the conductive pad in the dielectric structure includes forming a cavity in the dielectric layer, filling the cavity with copper, removing excessive copper on the first side, recessing a first surface of the dielectric layer with respect to a second surface of the copper, depositing the elastic bonding layer over the first and second surfaces, and removing the elastic bonding layer over the second surface of the copper.

It should be noted that the methods described above describe possible implementations, and that the operations and the steps may be rearranged or otherwise modified and that other implementations are possible. Furthermore, embodiments from two or more of the methods may be combined. From the foregoing, it will be appreciated that specific embodiments of the technology have been described herein for purposes of illustration, but that various modifications may be made without deviating from the disclosure. In addition, while in the illustrated embodiments certain features or components have been shown as having certain arrangements or configurations, other arrangements and configurations are possible. Moreover, certain aspects of the present technology described in the context of particular embodiments may also be combined or eliminated in other embodiments.

The devices discussed herein, including a semiconductor device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.” The term “exemplary” used herein means “serving as an example, instance, or illustration,” and not “preferred” or “advantageous over other examples.”

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor die, comprising:
a semiconductor substrate including integrated circuitry;
a dielectric structure over the semiconductor substrate, the dielectric structure including an elastic bonding layer located at a first side of the dielectric structure facing away from the semiconductor substrate; and
a conductive pad included in the dielectric structure, the conductive pad extending through the elastic bonding layer and operatively coupled to the integrated circuitry, wherein:
a thickness of the elastic bonding layer is predetermined based, at least in part, on a width of the conductive pad, the width being generally perpendicular to the thickness.

2. The semiconductor die of claim 1, wherein:
the elastic bonding layer has a first surface facing away from the semiconductor substrate; and
the conductive pad has a second surface facing away from the semiconductor substrate, the second surface being recessed by a depth with respect to the first surface.

3. The semiconductor die of claim 2, wherein the depth is proportional to the width of the conductive pad such that the thickness of the elastic bonding layer is predetermined based, at least in part, on the depth.

4. The semiconductor die of claim 2, wherein the thickness of the elastic bonding layer is at least ten (10) times the depth.

5. The semiconductor die of claim 1, wherein the elastic bonding layer includes a polymer material configured to accommodate stress generated by an irregularity at the first side.

6. The semiconductor die of claim 5, wherein the polymer material is flexible to deform in response to the stress generated by the irregularity at the first side.

7. The semiconductor die of claim 5, wherein the irregularity corresponds to a particle present at the first side.

8. The semiconductor die of claim 5, wherein the irregularity corresponds to the conductive pad, wherein:
the elastic bonding layer has a first surface facing away from the semiconductor substrate;
the conductive pad has a second surface facing away from the semiconductor substrate, the second surface being protruded above the first surface.

9. The semiconductor die of claim 5, wherein the irregularity originates from the conductive pad, wherein:
the elastic bonding layer has a first surface facing away from the semiconductor substrate;
the conductive pad has a second surface facing away from the semiconductor substrate, the second surface being recessed by a depth with respect to the first surface, wherein the depth is less than an increase in a thickness of the conductive pad in response to receiving thermal energy, the thickness being generally perpendicular to the width.

10. The semiconductor die of claim 1, wherein the conductive pad includes copper.

11. The semiconductor die of claim 1, wherein the elastic bonding layer includes at least one of polyimide, polybenzoxazole (PBO), polysiloxane-based material, or a sol-gel material.

12. The semiconductor die of claim 1, wherein the elastic bonding layer includes a modulus of elasticity of 2 GPa or less.

13. A semiconductor die assembly, comprising:
a substrate die; and
a semiconductor die attached to the substrate die, the semiconductor die including:
a semiconductor substrate having integrated circuitry;
a dielectric structure over the semiconductor substrate, the dielectric structure including an elastic bonding layer located at a first side of the dielectric structure facing away from the semiconductor substrate; and
a copper pad included in the dielectric structure, the copper pad extending through the elastic bonding layer and operatively coupled to the integrated circuitry, wherein:
a thickness of the elastic bonding layer is predetermined based, at least in part, on a width of the copper pad, the width being generally perpendicular to the thickness.

14. The semiconductor die assembly of claim 13, wherein the elastic bonding layer includes a polymer material configured to accommodate stress generated by an irregularity at the first side.

15. The semiconductor die assembly of claim 13, wherein the semiconductor die is a first semiconductor die and the copper pad is a first copper pad, and the semiconductor die assembly further comprises:
a second semiconductor die directly bonded to the first semiconductor die at the first side, wherein the second semiconductor die includes a second copper pad directly bonded to the first copper pad.

16. The semiconductor die assembly of claim 13, wherein the semiconductor die is a first semiconductor die and the elastic bonding layer is a first elastic bonding layer, and the semiconductor die assembly further comprises:
a second semiconductor die directly bonded to the first semiconductor die at the first side, wherein the second semiconductor die includes a second elastic bonding layer directly bonded to the first elastic bonding layer.

17. The semiconductor die assembly of claim 16, wherein:
the substrate die corresponds to an interposer die or a logic die; and
the first and second semiconductor dies correspond to memory dies.

18. A method, comprising:
providing a semiconductor die including a substrate having integrated circuitry;
forming a dielectric structure over the substrate, the dielectric structure including an elastic bonding layer located at a first side of the dielectric structure facing away from the substrate and a dielectric layer between the substrate and the elastic bonding layer; and
forming a conductive pad in the dielectric structure, the conductive pad extending through the elastic bonding layer and operatively coupled to the integrated circuitry, wherein:
a thickness of the elastic bonding layer is predetermined based, at least in part, on a width of the conductive pad, the width being generally perpendicular to the thickness.

19. The method of claim 18, wherein forming the conductive pad in the dielectric structure includes:
forming a cavity in the dielectric structure, the cavity extending through the elastic bonding layer and at least partially into the dielectric layer;
filling the cavity with copper; and
removing excessive copper on the first side.

20. The method of claim 18, wherein forming the conductive pad in the dielectric structure includes:
forming a cavity in the dielectric layer;
filling the cavity with copper;
removing excessive copper on the first side;
recessing a first surface of the dielectric layer with respect to a second surface of the copper;
depositing the elastic bonding layer over the first and second surfaces; and
removing the elastic bonding layer over the second surface of the copper.
